(19) United States
(12) Patent Application Publication
(10) Pub. No.: US 2009/0229652 A1
(43) Pub. Date: Sep. 17, 2009

(54) HYBRID SOLAR CONCENTRATOR

(76) Inventors: Jonathan K. Mapel, East Boston, MA (US); Marc Alexander Baldo, Cambridge, MA (US); Michael James Currie, Groton, MA (US); Shalom Goffri, Cambridge, MA (US); Timothy D. Heidel, Cambridge, MA (US); Michael Segal, Cambridge, MA (US)

Correspondence Address: LANDO & ANASTASI, LLP, ONE MAIN STREET, SUITE 1100, CAMBRIDGE, MA, 02142, US

(21) Appl. No.: 12/353,633

(22) Filed: Jan. 14, 2009

Related U.S. Application Data
(60) Provisional application No. 61/020,946, filed on Jan. 14, 2008.

(51) Int. Cl. H01L 31/052

(52) U.S. Cl. 136/246

(57) ABSTRACT

Solar concentrators are disclosed that improve the efficiency of PV cells and systems using them. The solar concentrators may be designed such that they include one or more chromophores that emit light to a PV cell. Various materials and components of the solar concentrators are also described.

### CROSS REFERENCE TO RELATED APPLICATIONS

This application claims priority under 35 U.S.C. § 119(e) to U.S. Provisional Application No. 61/020,946 filed Jan. 14, 2008 and entitled “Solar Concentrators and Devices and Methods Using Them,” which is incorporated herein by reference in its entirety.

### FEDERALLY SPONSORED RESEARCH

Certain embodiments of the technology disclosed herein may have been developed, at least in part, under NSF Grant No. 0403781 and DOE Grant No. DE-FC02-07ER46474. The government may have certain rights in the technology.

### BACKGROUND

1. Field of Invention

The present invention relates generally to solar concentrators and devices and methods using them. More particularly, certain examples disclosed herein are directed to solar concentrators that may be produced at a lower cost.

2. Discussion of Related Art

Photovoltaic (PV) cells may be used to convert solar energy into electrical energy. Many PV cells are inefficient, however, with a small fraction of the incident solar energy actually being converted into a usable current. Also, the high cost of PV cells limits their use as a renewable energy source.

### SUMMARY OF INVENTION

Aspects and embodiments are directed to hybrid solar concentrators that employ multiple methods and/or stages of light concentration, such as, for example, both luminescent concentration and geometric optical concentration, or concentration of light in two or more different wavelength ranges. According to one embodiment, a hybrid solar concentrator comprises a first luminescent solar concentrator comprising a first substrate having a first chromophore disposed in or on the first substrate to receive optical radiation, the first chromophore effective to absorb at least one wavelength of the optical radiation and to emit radiation, a first photovoltaic cell optically coupled to the first luminescent solar concentrator and configured to receive at least some of the emitted radiation, and an optical device optically coupled to the first luminescent solar concentrator and comprising a second photovoltaic cell configured to receive at least some of the optical radiation transmitted through the first substrate, wherein the first substrate has a curvature to refract and direct the at least some of the optical radiation transmitted through the first substrate toward the optical device.

In one example, the optical device comprises a second substrate and the second photovoltaic cell is a thin-film photovoltaic cell coupled to the second substrate. The second substrate may comprises, for example, any one of cadmium telluride, cadmium indium gallium selenide, copper indium sulfide, amorphous silicon, monocrystalline silicon, multicrystalline silicon, amorphous silicon/polysilicon micromorph, cadmium selenide, aluminum antimonide, indium phosphide, aluminum arsenide, gallium phosphide, gallium antimonide, dye-sensitized solar cells utilizing, for example, ruthenium dyes, or organic solar cells utilizing, for instance, fullerene, poly(3 -hexylthiophene), and phenyl-C61-butyric acid methyl ester.

In another example of the hybrid solar concentrator, the first and second photovoltaic cells are each selected to have different bandgaps. In another example, the emitted radiation has a wavelength that is red-shifted relative to the first wavelength. According to another example, the first photovoltaic cell is coupled to a first surface of the first substrate, and the optical device is arranged such that the second photovoltaic cell receives at least some of the optical radiation transmitted through a second surface of the first substrate. In one example, the first and second surfaces of the first substrates are at substantially 90 degrees relative to one another, and the optical device is disposed below the first substrate. In another example, the optical device comprises a second luminescent solar concentrator optically coupled to the second photovoltaic cell, wherein the second luminescent solar concentrator comprises a second substrate having a second chromophore disposed in or on the second substrate to receive at least some of the optical radiation transmitted through the first substrate, the second chromophore effective to absorb at least one wavelength of the transmitted optical radiation and to emit second radiation, wherein the second photovoltaic cell is configured to receive at least some of the second radiation. In another example, the optical device comprises a lens configured to focus the at least some optical radiation transmitted through the first substrate onto the second photovoltaic cell. According to another example, the optical device is disposed below a first surface of the first substrate, and the first surface of the first substrate is curved to refract at least some of the optical radiation transmitted through the first substrate onto the second photovoltaic cell.

The hybrid solar concentrator may further comprise at least one wavelength selective mirror disposed on the first substrate, the at least one wavelength selective mirror configured to transmit incident light in a first wavelength range and to reflect incident light in a second wavelength range. In one example, the first photovoltaic cell has a first bandgap including the second wavelength range, wherein the second photovoltaic cell has a second bandgap including the first wavelength range.

Another embodiment is directed to a method comprising acts of absorbing incident optical radiation with a first chromophore disposed in or on a first substrate, emitting emitted optical radiation from the first chromophore, receiving at least some of the emitted optical radiation at a first photovoltaic cell, and receiving at least some of transmitted optical radiation at a second photovoltaic cell, the transmitted optical radiation comprising at least some of the incident optical radiation that is transmitted through the first substrate.

In one example of the method, absorbing the incident optical radiation includes absorbing optical radiation having at least a first wavelength range, and emitting the emitted optical radiation includes emitting radiation having at least a second wavelength range that is red-shifted from the first wavelength range. In another example, the method further comprises refracting at least some of the transmitted optical radiation to focus the at least some transmitted optical radiation onto the second photovoltaic cell.

According to another embodiment, a hybrid solar concentrator comprises a first solar concentrator comprising a first substrate having a first chromophore disposed in or on the first substrate to receive incident optical radiation, the first chromophore effective to absorb at least one wavelength of the incident optical radiation and to emit first emitted radiation, a first photovoltaic cell optically coupled to a first edge of the first solar concentrator and configured to receive at least some of the first emitted radiation, a second solar concentrator disposed below a first surface of the first substrate, the second solar concentrator comprising a second substrate having a second chromophore disposed in or on the second substrate to receive transmitted optical radiation, the second chromophore effective to absorb at least one wavelength of the transmitted optical radiation and to emit second emitted radiation, and a second photovoltaic cell optically coupled to a second edge of the second substrate and configured to receive at least some of the second emitted radiation, wherein the transmitted optical radiation comprises at least some of the incident radiation which is transmitted through the first surface of the first substrate.

In one example of the hybrid solar concentrator, the first and second photovoltaic cells are each selected to have different bandgaps. The hybrid solar concentrator may further comprise a wavelength selective mirror disposed on the first surface of the first substrate, wherein the incident optical radiation comprises at least a first wavelength range and a second wavelength range, and wherein wavelength selective mirror configured to transmit incident optical radiation in the first wavelength range to provide the transmitted optical radiation, and to reflect incident optical radiation in the second wavelength range. In another example, at least one of the first and second substrates is a glass comprising a refractive index of at least 1.7. In another example, at least one of the first and second photovoltaic cells is a thin-film photovoltaic cell.

According to another embodiment, a solar concentrator comprises a diffusing plate that receives incident optical radiation and transmits diffuse optical radiation, a substrate disposed below and optically coupled to the diffusing plate, the substrate having a chromophore disposed in or on the substrate to receive the diffuse optical radiation, the chromophore effective to absorb at least one wavelength of the diffuse optical radiation and to emit emitted radiation, and a first photovoltaic cell optically coupled to the substrate and configured to receive at least some of the emitted radiation.

In one example, the diffusing plate is configured for lambertian scattering of the optical radiation. In another example, the emitted radiation has a wavelength that is red-shifted relative to the first wavelength. The solar concentrator may further comprise an anti-reflection coating disposed on at least one surface of the diffusing plate. The substrate may comprise, for example, any one of glass, cadmium telluride, cadmium indium gallium selenide, copper indium sulfide, amorphous silicon, monocrystalline silicon, multicrystalline silicon, and amorphous silicon/polysilicon micromorph. The diffusing plate may comprise, for example, one of opalescent glass, frosted glass, mechanically roughened plastics and glasses, chemically roughened plastics and glasses, surface-pattered plastics, and holographically patterned plastics. In another example, the substrate is a glass comprising a refractive index of at least 1.7. According to one example, the incident optical radiation is generated by an engineered light source. In another example, an orientation of the chromophore is in a range of approximately 70-90 degrees relative to a front face of the substrate.

Another embodiment is directed to a hybrid solar concentrator comprising a substrate having a chromophore disposed in or on the substrate to receive incident optical radiation, the chromophore effective to absorb at least one wavelength of the incident optical radiation and to emit emitted radiation, a first photovoltaic cell coupled to a first surface of the substrate and configured to receive at least some of the emitted radiation, a lens disposed below the substrate and configured to receive transmitted optical radiation, the transmitted optical radiation comprising at least some of the incident optical radiation which is transmitted through a second surface of the substrate, the lens further configured to refract the transmitted optical radiation, and a second photovoltaic cell optically coupled to the lens and configured to receive the refracted optical radiation.

In one example, the first and second photovoltaic cells are each selected to have different bandgaps. In another example, the second photovoltaic cell is a thin-film photovoltaic cell coupled to a second substrate.

According to another embodiment, a solar concentrator comprises a substrate having a chromophore disposed in or on the substrate to receive incident optical radiation, the chromophore effective to absorb at least one wavelength of the incident optical radiation and to emit emitted radiation, and a first photovoltaic cell optically coupled to the substrate and configured to receive at least some of the emitted radiation, wherein the substrate has a first angled surface configured to refract at least some of the emitted radiation toward the first photovoltaic cell.

In one example, the solar concentrator further comprises a mirror disposed on the first angled surface and configured to reflect the emitted radiation. In one example, the first angled surface is disposed at an angle in a range of about 90 degrees to about 135 degrees relative to a plane surface of the substrate. and the incident optical radiation is incident on the plane surface. In another example, the substrate further comprises a second angled surface configured to refract the emitted radiation toward the first photovoltaic cell. The solar concentrator may further comprise wavelength selective mirrors disposed on first and second angled surfaces, the wavelength selective mirrors configured to reflect the emitted radiation. In one example, the first photovoltaic cell has a width that is less than a thickness of the substrate. In another example, the first angled surface is a curved surface, and the first photovoltaic cell is optically coupled to the curved surface. The solar concentrator may further comprise a second photovoltaic cell optically coupled to the substrate, wherein the first angled surface is a curved surface, wherein the first photovoltaic is optically coupled to a second surface of the substrate, and wherein the second photovoltaic cell is optically coupled to the curved surface. In one example, the first and second photovoltaic cells are each selected to have different bandgaps.

According to another embodiment, a system comprises a portable device, a photovoltaic cell coupled to the portable device and configured to provide power to the portable device, and a solar concentrator optically coupled to the photovoltaic cell, the solar concentrator configured to receive incident optical radiation, to concentrate at least some of the incident optical radiation and to provide concentrated optical radiation to the photovoltaic cell.

In one example of the system, the solar concentrator comprises a substrate having a chromophore disposed in or on the substrate to receive the incident optical radiation, the chromophore effective to absorb at least one wavelength of the incident optical radiation and to emit emitted radiation, and the concentrated optical radiation includes the emitted radiation.

Still other aspects, embodiments, and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the various aspects and embodiments. Any embodiment disclosed herein may be combined with any other embodiment in any manner consistent with the objects, aims, and needs disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described in connection with the embodiment may be included in at least one embodiment. The appearances of such terms herein are not necessarily all referring to the same embodiment.

### BRIEF DESCRIPTION OF DRAWINGS

Various aspects of at least one embodiment are discussed below with reference to the accompanying figures, which are not intended to be drawn to scale. Where technical features in the figures, detailed description or any claim are followed by references signs, the reference signs have been included for the sole purpose of increasing the intelligibility of the figures, detailed description and/or claims. In the figures, each identical or nearly identical component that is illustrated in various figures is represented by a like reference sign. For purposes of clarity, not every component may be labeled in every figure. The figures are included to provide illustration and a further understanding of the various aspects and embodiments, and are incorporated in and constitute a part of this specification, but are not intended as a definition of the limits of the invention. In the figures:

FIG. 1 is an illustration of one example of a solar concentrator, in accordance with aspects of the invention;

FIG. 2 is a diagram of one example of a hybrid solar concentrator in accordance with aspects of the invention;

FIG. 3 is a diagram of one example of an array of solar concentrators in accordance with aspects of the invention;

FIG. 4 is a diagram of another example of a hybrid solar concentrator in accordance with aspects of the invention;

FIG. 5 is a diagram of another example of a hybrid solar concentrator in accordance with aspects of the invention;

FIG. 6 is a diagram of another example of a hybrid solar concentrator in accordance with aspects of the invention;

FIG. 7 is a diagram of another example of a solar concentrator in accordance with aspects of the invention;

FIG. 8 is a diagram of one example of a solar concentrator incorporating one or more mirrors in accordance with aspects of the invention;

FIG. 9 is a diagram of one example of a solar concentrator incorporating one or more mirrors in combination with a shaped substrate in accordance with aspects of the invention;

FIG. 10 is a diagram of another example of a solar concentrator incorporating one or more mirrors in combination with a shaped substrate in accordance with aspects of the invention;

FIG. 11 is a diagram of another example of a solar concentrator incorporating a diffuser in accordance with aspects of the invention;

FIG. 12 is a visualization of simulated optical quantum efficiency as a function of the angle of incidence of the optical radiation and the orientation of the chromophore for an example of the solar concentrator of FIG. 11;

FIG. 13 is a plot of simulated optical quantum efficiency as a function of molecular orientation for the same example of the solar concentrator of FIG. 11;

FIG. 14 is a plot of simulated optical quantum efficiency as a function of the angle of incidence of the optical radiation for three different molecular orientations for the same example of the solar concentrator of FIG. 11;

FIG. 15 is diagram of one example of a LSC/PV cell assembly coupled to a portable device, in accordance with aspects of the invention; and

FIG. 16 is a diagram of another example of a LSC/PV cell assembly coupled to a portable device, in accordance with aspects of the invention.

### DETAILED DESCRIPTION

Aspects and embodiments are directed to solar concentrators, as well as devices for and methods of using them. Embodiments of solar concentrators disclosed herein may provide significant advantages over existing devices, including higher efficiencies, fewer components, and improved materials and improved optical properties. These and other advantages will be recognized by the person of ordinary skill in the art, given the benefit of this disclosure. Certain examples of the solar concentrators disclosed herein may be used with low cost photovoltaic (PV) cells that comprise amorphous or polycrystalline thin films, as discussed further below.

It is to be appreciated that embodiments of the methods and apparatuses discussed herein are not limited in application to the details of construction and the arrangement of components set forth in the following description or illustrated in the accompanying drawings. The methods and apparatuses discussed herein are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments. Any references to embodiments or elements or acts of the systems and methods herein referred to in the singular may also embrace embodiments including a plurality of these elements, and any references in plural to any embodiment or element or act herein may also embrace embodiments including only a single element.

It is also to be appreciated that the phraseology and terminology used herein is for the purpose of description and should not be regarded as limiting. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, and upper and lower are intended for convenience of description, not to limit the present systems and methods or their components to any one positional or spatial orientation.

According to one embodiment, the devices and methods disclosed herein are operative to absorb and/or transfer at least some energy. The phrase “at least some” is used herein in certain instances to indicate that not necessarily all of the energy incident on the substrate is absorbed, not necessarily all of the energy is transferred, or not necessarily the energy that is transferred is all emitted as light. Instead, a portion or fraction of the energy may be lost as heat or other non-radiative processes in the solar concentrators disclosed herein. Certain materials or components are described herein as being disposed on or in another material or component. The term dispose is intended to be interchangeable with the term deposit and includes, but is not limited to, evaporation, co-evaporation, coating, blade coating, mesh coating, screen coating, slot-die coating, spray coating, gravure coating, curtain coating, painting, spraying, brushing, vapor deposition, casting, covalent association, non-covalent association, coordination or otherwise attachment, for at least some time, to a surface.

In solar energy transduction systems, the substitution of expensive photovoltaic devices with passive optical elements that redirect light, referred to as concentration, is a method by which the cost per watt of generated power may be reduced. In accordance with one embodiment, a luminescent solar concentrator (LSC) separates the photovoltaic functions of light collection and charge separation. For example, light may be gathered by an inexpensive collector (which may have a relatively large area) comprising a light absorbing material, as discussed below. Light absorbed by the collector may be redirected to a smaller area through guided energy transfer via an optical waveguide. Photovoltaic (PV) cells may be situated over the smaller area to receive the concentrated light. The ratio of the area of the collector to the area of the PV cell is known as the geometric concentration factor, G. One attraction of using a solar concentrator is that the complexity of a large area PV cell may be replaced by a simple optical collector. PV cells are still used, but large G values of a solar concentrator coupled to a PV cell can reduce the PV cost, potentially lowering the overall cost per watt of generated power. It is to be appreciated that although various embodiments of concentrators described below are referred to as “solar concentrators,” they are not limited to receiving and concentrating sunlight only, but instead may be used to concentrate light received from a variety of sources (including, but not limited to, the sun), as discussed further below.

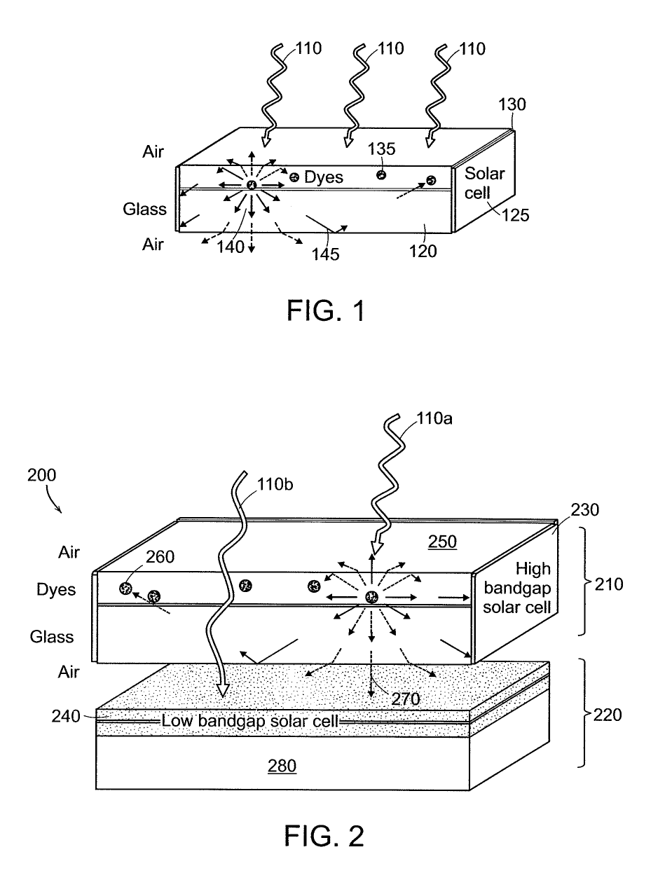

Referring to FIG. 1, there is illustrated a schematic example of a luminescent solar concentrator (LSC). The LSC includes a substrate 120 that is operative to trap and/or guide light. The terms substrate and waveguide may be interchanged for the purposes of this disclosure. The substrate 120 is optically coupled to at least one PV cell 125 (also referred to as a solar cell) at the edge 130 of the substrate 120. Light that is trapped by the substrate 120 may be directed to or otherwise coupled to the PV cell 125, such that the light may be converted into a current by the PV cell.

According to one embodiment, the substrate 120 may be selected such that one or more light absorbing material(s) or chromophores 135 may be disposed in or on the substrate 120 or the substrate may be impregnated with the chromophore. The chromophore 135 may be any substance that can absorb and/or emit light of a desired or selected wavelength. Any material that can receive a chromophore may be used in the substrates of the solar concentrators described herein.

Still referring to FIG. 1, solar radiation 110 is incident on the substrate 120 where it is absorbed by the chromophores 135 in the substrate 120. The substrate 120 need not be in direct sunlight but instead, may be used to receive direct, indirect and diffuse solar radiation, as discussed further below. An advantage of an LSC having the ability to receive and concentrate diffuse light is that such LSCs do not require solar tracking, which may further reduce system cost. The chromophore 135 can reradiate a photon of equal or lesser energy. Thus, energy from the absorbed solar radiation is re-radiated (as indicated by arrows 140) by the chromophore 135, and some portion of that reradiated energy will be confined within the substrate 120 by total internal reflection, as indicated by arrow 145. At least some of the trapped re-radiated energy may be guided toward the edge 130 for collection by the PV cells 125. One advantage of using LSCs over other optical concentration systems for photovoltiacs, such as mirrors, lenses, dishes and the like, is that very high concentration factors may be achieved without active cooling or high-accuracy mechanical tracking.

In accordance with one embodiment, in a typical LSC not all of the emitted photons from the chromophore 135 will be confined in the substrate 120. For a simple system that includes three layers, the trapping efficiency η_{Trap} of the photons isotropically emitted within a waveguide may be expressed as

$${η}_{Trap} = \sqrt{1 - \frac{{η}_{cladding}^{2}}{{η}_{core}^{2}}}$$

where η_{cladding} and η_{core} are the refractive indices of the cladding and core, respectively. For a simple air-clad glass waveguide, such as that illustrated in FIG. 1, with core and cladding refractive indices of 1.5 and 1, respectively, about 75% of the re-emitted photons will be trapped. In addition, not all of the light incident on the substrate 120 may be absorbed by the chromophore 135, and some light may pass through the substrate 120. Accordingly, at least some embodiments disclosed herein are configured to increase the amount of concentrated light, whether trapped in or transmitted though the substrate 120, and to provide a more efficient solar concentrator.

Referring to FIG. 2, there is illustrated one example of an optical system 200 including a luminescent solar concentrator (LSC) 202 coupled to a first PV cell 230, and a second optical device 230 that includes a second PV cell 240. The LSC 202 includes a substrate 250 having a chromophore 260 disposed therein to absorb and redirect light to the first PV cell 230 coupled to an edge of the substrate 250, as discussed above with reference to FIG. 1. The second PV cell 240 resides below the LSC 202 and receives filtered and/or concentrated light. For example, the second PV cell 240 may receive light 110b that is transmitted through the substrate 250 without being absorbed by the chromophore 260. In this example, the light 110b may be filtered by the LSC 202. The second PV cell 240 may also receive light (indicated by arrows 270) emitted by the chromophore 260 that escapes through the lower surface of the substrate 250. Thus, at least some of the light that is not trapped by the LSC 202 and converted by the first PV cell 230 may still be captured and converted by the lower PV cell 240, so the losses in the optical system 200 will be partially diminished.

The LSC 202 may be attached or otherwise coupled to the PV cells. In one example, the second PV cell 240 may be thin film photovoltaic cell coupled to a substrate 280, as shown in FIG. 2. The second PV cell 240 may be optically coupled to the LSC 202. Similarly, the first PV cell 230 may be a thin film PV cell. The combination of an LSC 202 with one or more thin film PV cells provides numerous advantages including, but not limited to, a cheaper method to improve the module efficiency compared to just the underlying PV cell alone.

In accordance with certain examples, an epoxy or adhesive may be used to attach the solar concentrators disclosed herein to a PV cell. The epoxy or adhesive may be chosen to have a refractive index close to that of the substrate. For example, PV cells may be attached using an adhesive or epoxy such that index mismatching may be avoided or substantially reduced. For example, to reduce the light coupling losses, it may be desirable to reduce optical reflections as light passes from the LSC into the PV cell. There may be an index mismatch between the waveguide and the PV cell, but this mismatch need not introduce large reflections if the PV cell is covered by an antireflection coating (most PV cells have them built into their structure). These antireflection coatings may be designed for light that is incident from air but can be redesigned for light that is incident from a solar concentrator. If the PV cells are attached to the substrate by an epoxy or an adhesive, the epoxy or adhesive may introduce unwanted reflections, and the thickness of the epoxy or adhesive may be difficult to control. By using epoxies which are index-matched to the waveguide, the antireflection coating of the PV cell may be designed for light incident from the waveguide and the exact thickness of the epoxy or adhesive is less important. Thus, by using an epoxy or adhesive whose index is matched to the substrate or waveguide, the overall efficiency of a PV cell may be increased.

Embodiments of the solar concentrators disclosed herein may be made using a variety of different materials for the substrates and a variety of different chromophores 208 such as, for example, the illustrative chromophores described herein or other suitable chromophores. Illustrative materials for use in the substrates include, but are not limited to, polymethylmethyacrylate (PMMA), glass, lead-doped glass, lead-doped plastics, aluminum oxide, polycarbonate, polyamide, polyester, polysiloxan, polyester resins, epoxy resins, ethyl cellulose, polyethylene terephthalate, polyethylenimine, polypropylene, poly vinyl chloride, soda lime glass, borosilicate glasses, acrylic glass, aluminum oxynitride, fused silica, halide-chalcogenide glasses, titania-doped glass, titania-doped plastics, zirconia-doped glass, zirconia-doped plastics, alkaline metal oxide-doped glass, alkaline metal oxide-doped plastics, barium oxide-doped glass, barium-doped plastics, and zinc oxide-doped glass, zinc oxide-doped plastics.

In accordance with one example, the solar concentrators disclosed herein may be produced using a high refractive index material. The term “high refractive index” refers to a material having a refractive index of at least 1.7. By increasing the refractive index of the substrate, the light trapping efficiency of the solar concentrator may be increased. Illustrative high refractive index materials suitable for use in the solar concentrators disclosed herein include, but are not limited to, high index glasses such as lead-doped glass, aluminum oxide, halide-chalcogenide glasses, titania-doped glass, zirconia-doped glass, alkaline metal oxide-doped glass, barium oxide-doped glass, zinc oxide-doped glass, and other materials such as, for example, lead-doped plastics, barium-doped plastics, alkaline metal oxide-doped plastics, titania-doped plastics, zirconia-doped plastics, and zinc oxide-doped plastics. In some examples any material whose light trapping efficiency is at least 80% of the quanta of radiation or more may be used as a high refractive index substrate.

In certain embodiments, the chromophore that emits light is, for example, a material is selected from the group consisting of rare earth phosphors, organometallic complexes, porphyrins, perylene and its derivatives, organic laser dyes, FL-612 from Luminophor JSC, substituted pyrans (such as dicyanomethylene), coumarins (such as Coumarin 30), rhodamines (such as Rhodamine B), oxazine, Exciton LDS series dyes, Nile Blue, Nile Red, DODCI, Epolight 5548, BASF Lumogen dyes (for instance: 083, 170, 240, 285, 305, 570, 650, 765, 788, and 850), other substituted dyes of this type, other oligorylenes, and dyes such as DTTC1, Steryl 6, Steryl 7, prradines, indocyanine green, styryls (Lambdachrome series), dioxazines, naphthalimides, thiazines, stilbenes, IR132, IR144, IR140, Dayglo Sky Blue (D-286), Columbia Blue (D-298), and organometallic complexes of rare earth metals (such as europium, neodymium, and uranium, such as, for example, those described in C. Adachi, M. A. Baldo, S. R. Forrest, Journal of Applied Physics 87, 8049 (2000); K. Kuriki, Y. Koike, Y. Okamoto, Chemical Reviews 102, 2347 (2002); H. S. Wang, et al, Thin Solid Films 479, 216 (2005); Y. X. Ye, et al, Acta Physica Sinica 55, 6424 (2006).

In accordance with certain examples, the solar cell devices disclosed herein may be arranged with other solar cell devices disclosed herein to provide an array of solar cells. For example, the system may comprise a plurality of photovoltaic cells constructed and arranged to receive optical radiation from the sun or another light source, wherein at least one of the plurality of photovoltaic cells is coupled to a solar concentrator as described herein. In particular, the solar concentrator of the system may be any one or more of the solar concentrators disclosed herein. In addition, the system may include a plurality of solar concentrators with each of the solar concentrators being the same type of solar concentrator. In other examples, many different types of solar concentrators may be present in the system.

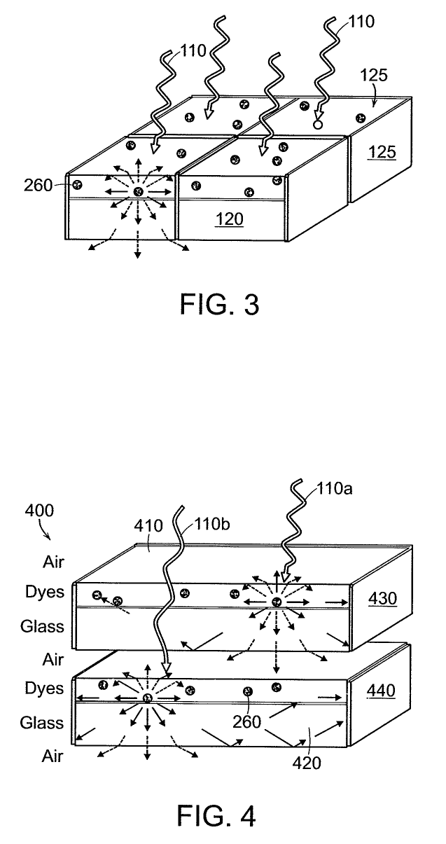

In accordance with certain examples, the PV cells may be embedded or otherwise integrated into the solar concentrators disclosed herein. For example, where the substrate is producing using one or more polymers, e.g., a plastic, it may be desirable to embed the PV cell into the waveguide rather than attach the PV cell at an edge of the waveguide. A configuration of such embedded PV cell is shown in FIG. 3. In embodiments where the concentrator is produced using a plastic, the PV cell can be embedded in the plastic melt when the liquid material is cast or injection molded. This process permits omission of any epoxy or adhesive joints to attach a PV cell to the solar concentrator. As the joints have been removed, the index matching to a substrate is not required, and the antireflection coating on the PV cell may be designed directly for light incident from the waveguide. In addition, in a solar concentrator that is limited in geometric optical gain by re-absorption losses, very large modules can be made with lower optical gains. For example, a chromophore may limit the concentration factor to 100, e.g., corresponding to waveguide dimensions of 80 cm×80 cm×2 mm. If a module with larger dimension is desired, e.g., 160 cm×160 cm×2 mm, four concentrators would be tiled in an array inside the module. This design constraint may be avoided by embedding the PV cells in a grid within the solar concentrator, so the module can be made larger without sacrificing performance due to chromophore re-absorption. The plurality of solar cells may be of identical or different types, corresponding to the different optical intensity incident on each. The solar cells may be designed to absorb light from a single direction. In this case, two solar cells may be placed adjacent to each other to receive light incident from two concentrators on opposing sides. The solar cells may also be designed to absorb light from two directions, i.e. bifacial solar cells. In this case, the area of solar cells can be substantially reduced.

The solar concentrators disclosed herein may be used with many different types of PV cells and PV cells having different efficiencies. By using the solar concentrators disclosed herein, the efficiency of each PV cell need not be the same. For example, it may be desirable to use a high efficiency PV cell without a concentrator and use a low efficiency PV cell with a concentrator to provide substantially the same efficiency for each of the PV cells. In addition, it may be desirable to selectively position the PV cells in an array to utilize the different efficiencies. Electrical power losses from heating increase with increasing current flowing in a module circuit. The current is minimized with a serial configuration. For this reason, the typical configuration of individual solar cells when connected in a module is in series. For cells connected in this way, it is desirable that each cell passes the same amount of current. Otherwise, PV cells with lower currents will limit the total current that can flow through the whole module, limiting the power conversion efficiency. In a typical module, effort and cost is devoted to testing and sorting individual cells such that all cells to be put into a module are as close to identical in performance as possible. Also, they are typically all the same size. The light intensity reaching the edges of a luminescent solar concentrator (LSC) depends on position on the guide. Since the light intensity depends on position, the current passing through each solar cell should also depend on position. If identical PV cells are used (either in size or performance), the module power conversion efficiency will be limited by the cell receiving the least light and thus passing the least current.

According to another embodiment, the geometry of the PV cell may also be tailored or designed such that PV cells having different efficiencies may be used with one or more of the solar concentrators disclosed herein. For example, the amount of light reaching each of the collection edges depends, ay least in part, on waveguide geometry. For manufacturing simplicity and cost, many solar concentrators may be produced in rectangular or square configurations, but other geometries are possible. For a simple rectangular case, the light reaching the comers will be lower than those edges closest to the center as optical losses increase with the distance light travels in the waveguide. By adjusting the PV cell efficiency as a function of position, higher efficiency cells can be used in the edges near the comers and lower efficiency cells can be used in the edges near the solar concentrator center. Using this arrangement, the current flowing through each PV cell may be substantially equal and module efficiency is not limited by lower current PV cells. This arrangement permits for the use of cells of variable performance efficiencies instead of using the lower efficiency cells in less valuable lower efficiency modules.

In certain examples, the dimensions of the PV cells may also be adjusted to provide similar efficiencies. For example, by adjusting the cell dimensions of identically efficient cells, similar current matching is possible. If all cell heights are identical (set, for example, by the edge thickness), then the cell lengths may be altered to accommodate the differing light intensities as a function of position. PV cells at the edges closest to the comers may be longer, and cells at the edges closest to the concentrator center may be shorter. Similarly, referring again to FIG. 2, the sizes of the first PV cell(s) 230 may be varied relative to the sizes of the second PV cell(s) 240. The use of such variable size PV cells with the concentrators disclosed herein provides similar efficiencies to increase the overall efficiency of a PV cell array.

According to one embodiment, two or more PV cells with different electrical bandgaps may be used, such that one of the PV cells absorbs light within a first wavelength range and at least one of the other PV cells absorbs light within a second wavelength range different from the first wavelength range. For example, referring again to FIG. 2, LSC 202 may be designed to operate with the first PV cell 230 being a high bandgap PV cell and the second PV cell 240 being a low bandgap PV cell. Thus, certain light wavelengths 110a may be absorbed by the chromophore 260 and re-transmitted for absorption by the first PV cell 230, while other light wavelengths 110b are transmitted through the LSC 202 and absorbed by the second PV cell 240. Converting light to electrical current with multiple electrical bandgaps in a tandem configuration, such as illustrated in FIG. 2, allows a higher fraction of the light's optical power to be converted to electrical power. Furthermore, in an optical system, (such as optical system 200) comprised of a top system comprised of a concentrator 202 collecting light to be converted at a high bandgap PV cell 230 and a bottom system 230 comprised of a lower electrical bandgap thin film photovoltaic 240, the requirements of current density matching are alleviated as the two systems no longer need to be connected serially. By contrast, as discussed above, in a serial configuration the currents desirably match or the cell with the lowest current can limit the overall current and thus overall efficiency of the device.

In accordance with another embodiment, two or more waveguides may be optically coupled such that one of the waveguides absorbs light within a first wavelength range and at least one of the other waveguides absorbs light within a second wavelength range different from the first wavelength range. Devices that include two or more waveguides are referred to in certain instances herein as tandem devices. The tandem device may include two solar concentrators as described herein or may include a solar concentrator coupled to an existing thin film photovoltaic cell, as discussed above with reference to FIG. 2.

In one embodiment, a tandem luminescent solar concentrator (LSC) is produced by stacking two or more waveguides onto each other or otherwise optically coupling two or more waveguides. Referring to FIG. 4, one example of a tandem luminescent solar concentrator 400 comprises a first waveguide 410 disposed or stacked on a second waveguide 420. According to one embodiment, the waveguides 410, 420 may be attached or otherwise coupled to one or more PV cells 430, 440 with selected bandgaps so a greater fraction of each photon's power will be extracted. For example, the top waveguide 410 may be configured to concentrate visible radiation on a first PV cell 430 coupled to the waveguide 410. PV cell 430 may be, for example, a gallium indium phosphide (GaInP) PV cell. The bottom waveguide 420 may be configured to concentrate a different wavelength range of radiation on a second PV cell 440 coupled to the waveguide 420. In one example, the second PV cell 440 may be a GaAs PV cell. In another example, the bottom waveguide 420 includes a chromophore 260 that is configured to absorb radiation with wavelengths greater than 650 nm and provide such radiation to the second PV cell 440. The second PV cell 440 may be, for example, a silicon PV cell.

In certain examples, numerous different types of PV cells may be used with an LSC to provide a tandem device, and the exact type and nature of the PV cell is not critical. Illustrative PV cells for use with a LSC in a tandem device include, but are not limited to, chalcopyrite based (CuInSe₂, CuInS₂, CuGaSe₂), cadmium telluride (CdTe) amorphous, nanocrystalline, polycrystalline, or multicrystalline silicon, amorphous silicon-germanium (SiGe), germanium (Ge), cadmium selenide, aluminum antimonide, indium phosphide, aluminum arsenide, gallium phosphide, gallium antimonide, dye-sensitized solar cells utilizing, for example, ruthenium dyes, or organic solar cells utilizing, for instance, fullerene, poly(3-hexylthiophene), or phenyl-C61-butyric acid methyl ester. The LSC may be used with any one or more of the LSC's described herein. In some examples, the LSC may be used with two or more thin film PV cells, whereas in some examples two or more LSC's may be used with a single thin film PV cell. Other combinations of LSC's and thin film PV cells to provide a tandem device will be readily selected by the person of ordinary skill in the art, given the benefit of this disclosure.

According to another embodiment, an optical system is configured to concentrate absorbed light by the LSC process discussed above and also to redirect and concentrate non-absorbed light through refraction. The power conversion efficiency of such a hybrid concentrator system may be increased relative to a conventional LSC system due to the ability to capture and concentrate a greater percentage of incident light. Absorbed light is concentrated by luminescence and transmitted light, which in a conventional system may go unused, is optically concentrated by refraction. Refraction may be achieved by the shape and/or configuration of the LSC itself and/or by an optical element optically coupled to the LSC, as discussed further below.

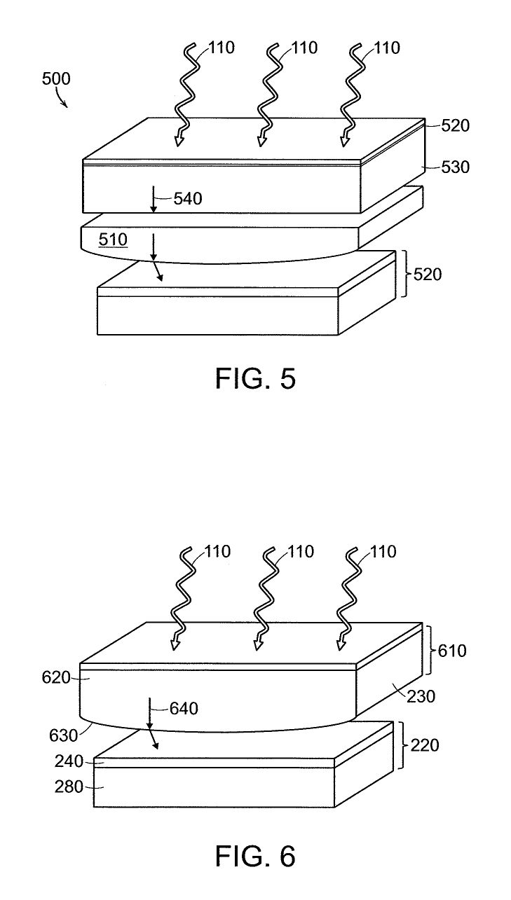

Referring to FIG. 5, there is illustrated one example of a hybrid solar concentrator including an LSC 500 optically coupled to a lens 510. The LSC 230 includes a substrate 520 having a chromophore 260 disposed therein to absorb and redirect light to a first PV cell 530 coupled to an edge of the substrate 520, as discussed above with reference to FIGS. 1 and 2. Light that is transmitted through the substrate 520 may be refracted by the lens 510 and directed onto a second PV cell 540, as indicated by arrows 550. Thus, the first PV cell 530 receives the luminescence-concentrated light and the second PV cell 540 receives the optically concentrated light. Both PV cells 530, 540 may be reduced in spatial extent relative to the same type of PV cell configured to receive non-concentrated light. In one example, the second PV cell 540 may be a thin film PV cell coupled to a substrate (not shown), similar to the example illustrated in FIG. 2.

According to one embodiment, the first and second PV cells 530, 540 may have different bandgaps to absorb light with different wavelength ranges so a greater fraction of each photon's power will be extracted.

In the example illustrated in FIG. 5, the lens 510 is a plano-convex lens with one planar surface and an opposing convex surface; however, it is to be appreciated that the lens 510 may have a variety of shapes and configurations and is not limited to a plano-convex lens. For example, the lens 510 may be bi-convex, or plano-concave. Similarly, the lens 510 may be cylindrical or aspherical. As will be appreciated by those skilled in the art, the exact shape of the lens 510 is not critical provided that the lens is shaped and arranged to direct light transmitted through the substrate 520 onto the second PV cell 540. The size and shape of the lens 510 may be selected based at least in part on the size and shape of the substrate 520 and/or the second PV cell 540.

According to one embodiment, the dimensions of the substrate may vary depending on the desired efficiency, overall size of the concentrator and the like. In particular, the substrate may be thick enough such that a sufficient amount of light may be trapped, e.g., 70-80% or more of the quanta of radiation (i.e., 7-80% of the incident photons). In certain examples, the thickness of the substrate may vary from about 1 mm to about 4 mm, e.g., about 1.5 mm to about 3 mm. The overall length and width of the substrate may vary depending on its intended use, and in certain examples, the substrate may be about 10 cm to about 300 cm wide by about 10 cm to about 300 cm long. The exact shape of the substrate may also vary depending on its intended use environment. In some examples, the substrate may be planar or generally planar, whereas in other examples, the substrate may be non-planar. In certain examples, opposite surfaces of the substrate may be substantially parallel, as illustrated in FIG. 5. However, in other examples opposite surfaces may be diverging or converging. For example, the top and bottom surfaces may each be sloped such that the width of the substrate at one end is less than the width of the substrate at an opposite end. The divergence or convergence of surfaces may exist in one or two dimensions.

Referring to FIG. 6, there is illustrated another example of a hybrid solar concentrator comprising an LSC 610 disposed above and optically coupled to an optical element 230. As discussed above with reference to FIG. 2, in one example, the optical element 230 comprises a thin film PV cell 240 disposed on a substrate 280. In one embodiment, the substrate 620 of the LSC 610 is shaped to direct transmitted light to the second PV cell 240. As illustrated in FIG. 6, by curving at least one surface 630 of the substrate 620, light 640 transmitted through the surface 630 of the substrate 620 may be refracted and thus directed to the second PV cell 240. In this example, the need for the lens 510 may be obviated as the substrate 620, through its shape and optionally other characteristics, may optically concentrate the transmitted light 640 by refraction. Alternatively, the lens 510 may be used in conjunction with the shaped substrate 620 such that each element (i.e., the lens and the substrate) may contribute to achieve a desired degree of refraction. The curved surface may be concave, increasing the geometric concentration of transmitted light above unity. A wide range of curvatures will increase geometric concentration. For example, the radius of curvature may be in a range of between about 0.5 and 10,000 times of the length of the substrate. The lower the radius of curvature, the greater the amount of geometric concentration of transmitted light onto the second PV cell 240. The curved surface 630 may have a radius of curvature in one or two dimensions. The radius of curvature may be different for each dimension.

As discussed above, according to one embodiment, the first and second PV cells 230, 240 may have different bandgaps to absorb light with different wavelength ranges so a greater fraction of each photon's power will be extracted.

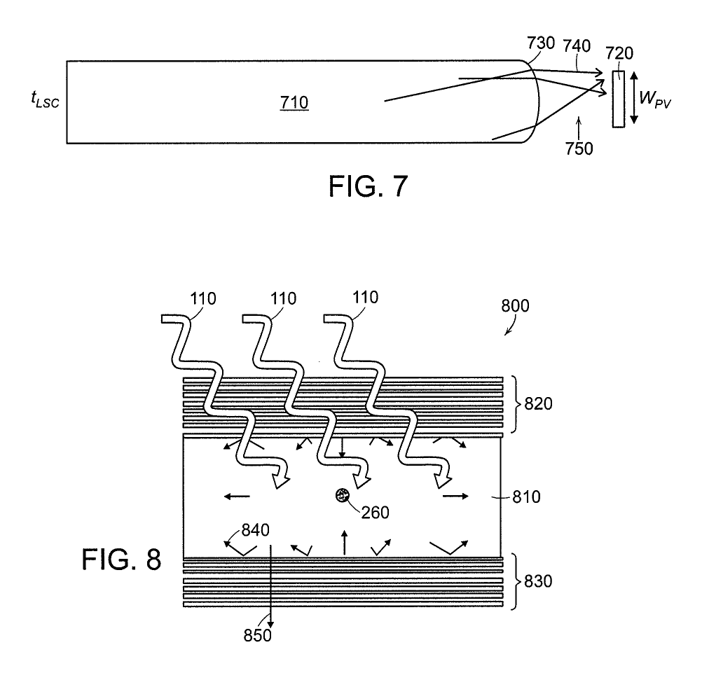

Referring to FIG. 7, there is illustrated another example of a solar concentrator including a shaped substrate 710 optically coupled to a PV cell 720. As illustrated, in one example, the edge(s) 730 are curved such that light is refracted to the PV cell 720. An air gap 750 is provided between the substrate 710 and the PV cell 720 to allow for focusing of the light 740, and the PV cell 720 is placed at the focal point. The light 740 is concentrated by refraction such that the dimension of the PV cell 720 may be reduced, as discussed above. Specifically, in one example, the width, w_{PV}, of the PV cell 720 may be smaller than the thickness, t_{LSC}, of the substrate 710, as illustrated in FIG. 7. It is to be appreciated that the air gap 750 may be filled with air or another medium, such as a gas other than air, or a fluid, e.g., a gas, liquid, or combinations thereof.

According to another embodiment, the solar concentrators disclosed herein may include one or more wavelength selective mirrors disposed thereon. For example, as solar radiation 110 is incident on the substrate, some of the incident light may be reflected away from the substrate resulting in lower capturing of the light. By including at least one wavelength selective mirror on a surface of the substrate, the light may be retained internally or directed to be transmitted through a selected surface of the substrate to a PV cell coupled to the solar concentrator. An illustration of an example of this configuration for a solar concentrator is shown in FIG. 8. In the illustrated example, the solar concentrator 800 comprises a substrate 810 comprising one or more chromophores 260 disposed on or in the substrate 810, as described above. The solar concentrator 800 also comprises a first selective mirror 820 on a top surface of the substrate 810 and, optionally, a second selective mirror 830 on a bottom surface of the substrate 402, as illustrated in FIG. 4. The first selective mirror 820 may be configured such that the incident light, shown as arrows 110, is permitted to be passed by the first selective mirror 820 into the substrate 810. The first selective mirror 820 may be designed such that reflected light, such as reflected light 840, is retained with the substrate 810, e.g., the reflected light is reflected back into the substrate 810 by the first selective mirror 820. Similarly, the second selective mirror 830 may be designed such that it reflects light of certain wavelengths (e.g., light emitted by the chromophore 260) back into the substrate 810, while permitting light of other wavelengths, indicated by arrow 850, to pass through to an underlying PV cell (not shown in FIG. 8). The use of reflective mirrors permits trapping of the light within the substrate 810 to increase the overall efficiency of the solar concentrator 800. In addition, by using wavelength selective mirrors, light of different wavelengths can be directed to PV cells having bandgaps optimized for those wavelengths, as discussed above.

In certain examples, the wavelength selective mirrors may comprise alternating thin films of, for example, one or more dielectric materials to provide a thin film stack that is operative as a wavelength selective mirror. In some examples, the thin films stacks are produced by disposing thin film layers having different dielectric constants on a substrate surface. The exact number of thin films in the thin film stack may vary depending, for example, on the materials used, the desired transmission and reflection wavelengths and the like. In some examples, the thin film stack may include from about 6 thin film layers to about 48 thin film layers, more particularly about 12 thin film layers to about 24 thin film layers, e.g., about 16 thin film layers to about 12 thin film layers. The exact materials used to produce the thin film layers may also vary depending on the desired number of thin films layers, the desired transmission and reflection wavelengths and the like. In some examples, a first thin film may be produced using, for example, a material such as polystyrene, cryolite and the like. A second thin film may be disposed on the first thin film using, for example, metals such as tellerium, zinc selenide and the like. In some examples, each of the thin films may have a thickness that varies from about 20 nanometers to about 100 nanometers, more particularly, about 30 nanometers to about 80 nanometers, e.g., about 50 nanometers. One advantage of using thin films is that mirrors comprised of thin films may permit retention of light at all angles of incidence and polarizations to further increase the light trapping efficiency of the solar concentrator. Solar concentrators having such thin film mirrors can receive more light thus increasing the efficiency of the PV cell device.

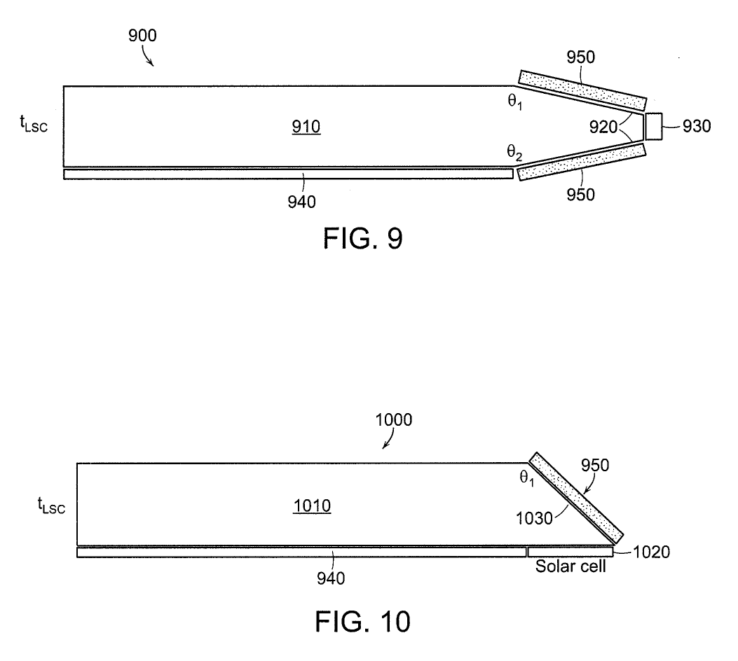

Referring to FIG. 9, there is illustrated another example of a solar concentrator incorporating mirrors in combination with a shaped substrate to facilitate light concentration. In the illustrated example, the LSC 900 comprises a substrate 910 with angled surfaces 920 coupled to a PV cell 930. In one example, the substrate 910 includes a dye coating layer 940 comprising a chromophore to concentrate light by luminescence, as discussed above. According to one embodiment, mirrors 950 are coupled to the angled surfaces 920 and configured to reflect light so as to direct the light toward the PV cell 930. The mirrors 950 may be, for example, mirrored films, as discussed above, or mirrored substrates. In one example, the mirrors 950 are attached to the angled surfaces 920 using an optical adhesive; however, it is to be appreciated that numerous methods of attachment are possible, as will be recognized by those skilled in the art given the benefit of this disclosure. The angles θ₁ and θ₂ of the two angled surfaces 920 may be the same or different, and may be any angle in the range of about 90 degrees to about 180 degrees. The angles θ₁ and θ₂ may be selected based on a variety of factors, including, for example, the desired size of the PV cell 930 relative to the thickness t_{LSC} of the substrate 910, the reflective properties of the mirrors 950, the refractive index of the substrate, etc. Because the light incident on the PV cell 930 may be concentrated by focusing the light toward the PV cell 930 using the mirrors 950 and shaped substrate 910, and may also optionally be concentrated by luminescence using chromophores as discussed above, the PV cell 930 may be reduced in spatial extent relative to the same type of PV cell configured to receive non-concentrated light.

Another example of a solar concentrator 1000 incorporating one or mirrors in combination with a shaped substrate is illustrated in FIG. 10. In this example, the PV cell 930 is disposed below the substrate 1010, optically coupled to at least a portion of the lower surface of the substrate, rather than to the edge surface of the substrate as shown in FIG. 9. Accordingly, the substrate 1010 includes an angled surface 1030 disposed at an angle θ₁. A mirror 950 is coupled to the angled surface 1030, as discussed above. The combination of the angle θ₁ and reflective properties of the mirror 950 may concentrate and direct light toward the PV cell 1020. In one example, the angle θ₁ may is in a range from about 90 degrees to about 135 degrees so as to concentrate light toward the PV cell 1020. According to one example, the PV cell 1020 may capture both light reflected by the mirror 950 as well at least some light that would otherwise be lost out of the lower surface of the substrate 1010. It is also to be appreciated that the example solar concentrators illustrated in FIGS. 9 and 10 may be used in combination other solar concentrators, for example, those illustrated in FIGS. 2 and 4, to provide a hybrid system including two or more PV cells and configured to both optically concentrate light (e.g., by refraction) and to concentrate light by luminescence.

In accordance with certain examples, the various materials used in the concentrators disclosed herein, e.g., chromophores, thin films, etc., may be disposed using numerous different methods including, but not limited to, painting, brushing, spin coating, casting, molding, sputtering, vapor deposition (e.g., physical vapor deposition, chemical vapor deposition and the like), plasma enhanced vapor deposition, pulsed laser deposition and the like. In some examples, organic vapor phase deposition (OVPD) may be used to deposit at least one of the components of the solar concentrators disclosed herein. OVPD may be used, for example, to dispose or coat a waveguide with one or more chromophores, red-shifting agents, heavy metals or the like. In some examples, OVPD may be used to produce a solar concentrator by disposing a vapor phase of the chromophore on a substrate and optionally curing or heating the substrate. Illustrative devices for OVPD are commercially available, for example, from Aixtron (Germany). Suitable methods, parameters and devices for OVPD are described, for example in Baldo et al., Appl. Phys. Lett. 71(2), 3033-3035, 1997.

According to another embodiment, the trapping efficiency of emitted photons within the solar concentrator can be adjusted by controlling emission directionality. For example, the trapping efficiency can be increased beyond that of a population of randomly oriented emitters, whose far-field emission pattern will be isotropic (uniform in all directions). Any deviation from a completely random orientation of emitters will alter the overall confinement efficiency, which can consequently range from zero to unity.

In some examples, it is presently desirable to increase the trapping efficiency above that of an randomly oriented population of emitters to increase the optical quantum efficiency of the solar concentrator. For an isolated chromophore, the directionality of emission is very similar to the directionality of absorption. In general, a chromophore optimally aligned for high light absorption efficiency will have a low trapping efficiency. Similarly, a chromophore optimally aligned for high trapping efficiency will have low light absorption efficiency. This tradeoff arises from the requirement to change the direction of light in the solar concentrator. For example, referring again to FIG. 1, incident light 110 that is near-normal to the plane of the substrate surface is ideally emitted near-parallel that that same surface in order to maximize trapping efficiency.

According to one embodiment, there are two methods that may be employed to increase the product of absorption efficiency and confinement efficiency. The utilization of near-field energy transfer separates the process of light absorption and emission onto physically distinct chromophores, breaking the directional symmetry of absorption and emission. Consequently, chromophores which principally function to directly absorb the solar radiation can be oriented with maximum directionality near-parallel to the direction of the light source such that the absorption efficiency is increased. Chromophores which principally function to emit light can be oriented near-parallel to the plane of the solar concentrator such that trapping efficiency is increased. In both cases, the increase is relative to the situation of a random distribution of chromophore orientations. Near-field energy transfer links absorption and emission of distinct chromophores in close proximity. By restricting the angular distribution of chromophore orientations, the efficiencies of absorption and confinement can be independently controlled. A restriction in distribution of one or both classes of chromophores can result in an increase of the product of absorption and confinement efficiency, which may increase the total power conversion efficiency of the solar concentrator.

There are several ways by which chromophore alignment can be achieved.

The chromophores reside in a local environment which can constrain their physical orientation. In one example, the local environment, or matrix, can be mechanically patterned or stretched to achieve anisotropy in its physical properties. The chromophores can be disposed onto the matrix before or after its alteration. The molecular structure of the matrix can be directly designed to favor a physical anisotropy, as with block copolymers. For example, the emitters can reside in this matrix and be sterically hindered to adapt a specific conformation to reduce its energetic interaction with the matrix. In another example, the emitters can be physically linked to the matrix, either through covalent bonds or Van der Waals interactions, such that a given alignment is predominant.

Certain chromophores possess an electronic dipole which can interact with local electric fields. If the dipoles exist within a liquid or viscous media, they can rotate or align to the electric field, lowering their free energy. Macroscale coordination of physical structure in response to electronic stimuli occurs in liquid crystals and forms the operational basis for liquid crystal displays (LCDs). According to one example, long term orientational stability may be achieved if chromophores and liquid crystals are aligned in a viscous media and then solidified. Solidification may occur through a number of means, including, for example, polymerization induced by optical or thermal excitation.

The chromophores can be aligned to the interface between the coating and substrate through direct self-assembly. For example, the emitters can covalently bind to the substrate and pack densely to maximize interface linkage. Depending on the physical structure of the chromophore, dense packing can result in physical alignment. For example, the linear physical structure of alkanethiols and octadecyltrichlorosilanes result in self assembly of monolayers on metallic and oxide substrates, respectively. These layers can be deposited sequentially, retaining alignment throughout.

The orientation of certain chromophores in an operational solar concentrator may be restricted if, during manufacture, a subset are made optically inactive. For example, if a fabrication method is used that results in an isotropic emitter pattern, a subset can be turned off, resulting in a narrower angular range of emitters. This deactivation can be controlled if the emitters exhibit an anisotropic interaction with some deactivating force. For example, this could be absorption and oxidation following absorption of high energy electromagnetic radiation or a particle stream. The anisotropic interaction may be due to polarization or directionality of incoming radiation.

For solar concentrators that are formed by coating chromophores on a waveguide substrate, the physical orientation can be controlled if the emitter resides in a viscous medium that is extruded through a small opening. For example, die heads in roll coaters can be very small fluid output slits. During fluid travel through these slits, materials (both chromophores and the matrix) can align to the travel direction and be coated in an anisotropic manner. Solidification of the fluid coating may occur through a number of means, including, for example, polymerization induced by optical or thermal excitation.

According to one embodiment, a second method which may be employed to increase the product of absorption and confinement efficiency involves the use of an optical element situated between the coated substrate and the illumination source and separated by a physical gap. The optical element functions to redirect the angle of incidence of the incoming light from the sun. One example of an optical element is a light diffusing plate. By using a diffusing plate, light which is principally incident near normal to the solar concentrator can be distributed to a wider range of angles. Stated another way, direct light may be transformed into diffuse light. In this configuration, light may be absorbed with high efficiency by chromophores oriented to increase confinement efficiency. Diffusing plates and other optical elements to redirect light be used independently or in addition to energy transfer.

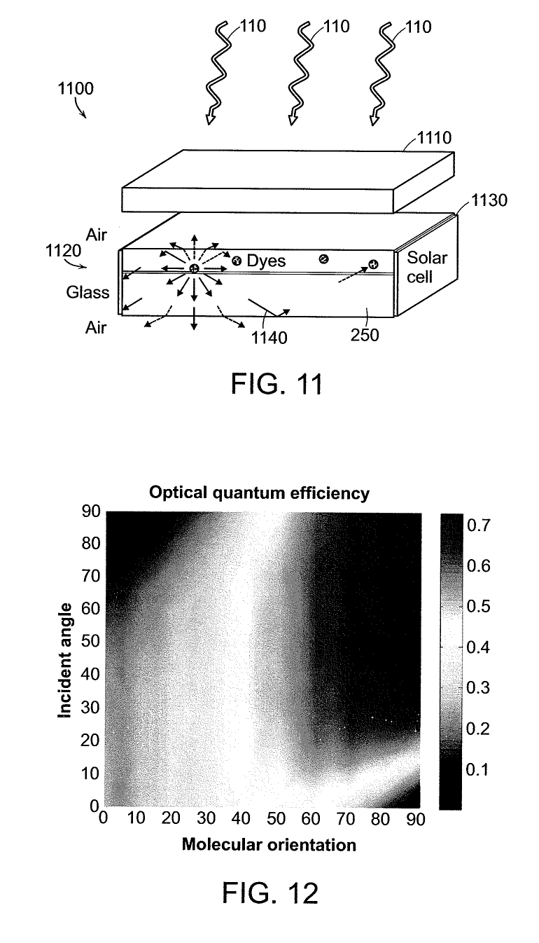

Referring to FIG. 11, there is illustrated another example of a solar concentrator system. In the illustrated example, the system 1100 comprises a diffusing plate 1110 disposed above an LSC 1120 coupled to a PV cell 1130. As discussed above with reference to FIGS. 1 and 2, the LSC 1120 includes a substrate 610 having a chromophore 260 disposed therein to absorb and redirect light 1140 to the PV cell 1130 coupled to an edge of the substrate 610. The diffusing plate 1110 serves to change the direction of the optical radiation 110 before it is incident on the substrate 610. In one example, the diffusing plate 1110 is configured for lambertian scattering of the optical radiation 110. In certain examples, numerous different types of light diffusers may be used with an LSC, and the exact type and nature of the diffuser is not critical. Illustrative light diffusers for use with a LSC include, but are not limited to, opalescent glass, frosted glass, mechanically roughened plastics and glasses, chemically roughened plastics and glasses, surface-pattered plastics, and holographically patterned plastics. In one example, anti-reflection coatings (not shown) may be provided on the upper surfaces of either (or both) of the diffusing plate 1110 and/or the substrate 610 to reduce or prevent reflection of the optical radiation 110 away from the solar concentrator.

A monte carlo simulation was performed for a solar concentrator such as that illustrated in FIG. 10 to illustrate the optical quantum efficiency of such a system for various orientations of the chromophore 260. For this simulation, it is assumed that one chromophore 260 absorbs and emits. The chromophore loading of the substrate 610 is such to yield 95% absorption for light incident at 30 degrees in a single pass of light having a wavelength of 600 nm. A cosine-squared emission pattern is assumed, which results in highest confinement efficiency for emitters oriented at 90 degrees. Orientation of the chromophores (emitters) is specified relative to the front face of the LSC 1120. A diffusing plate 1110 with lambertian scattering is placed above the LSC 1120. The LSC 1120 has dimensions corresponding to a geometric gain, G, of 250. The results of this simulation are illustrated in FIGS. 12-14.

FIG. 12 illustrates optical quantum efficiency as a function of the angle of incidence of the optical radiation (vertical axis) and the orientation of the chromophore (horizontal axis), for the above simulation. The optical quantum efficiency is nearly constant and highest for a chromophore orientation of between about 70 degrees and 90 degrees.

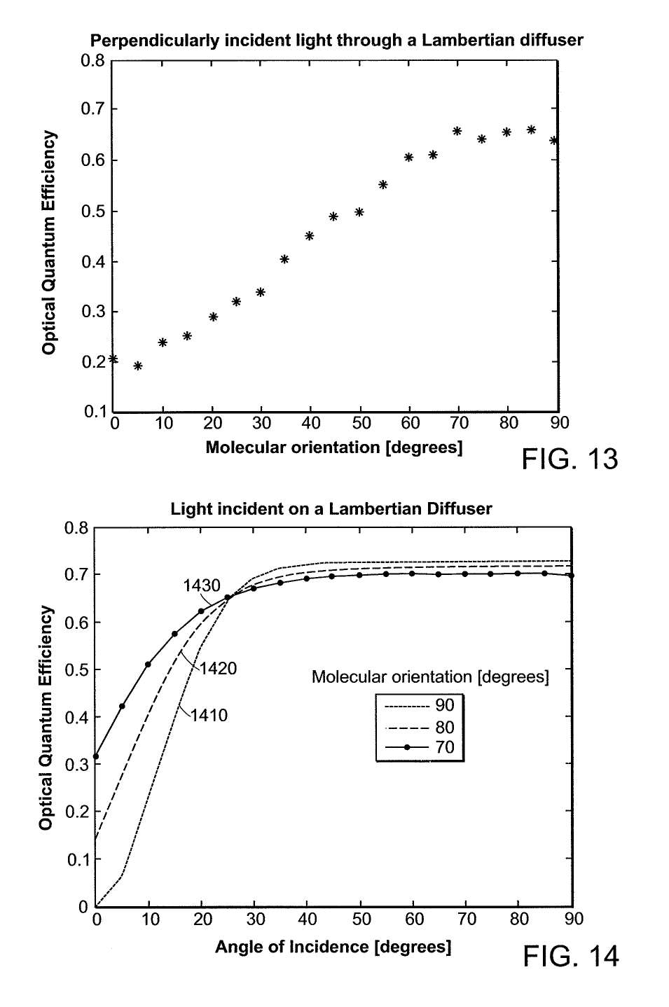

Referring to FIG. 13, there is illustrated a plot of the optical quantum efficiency (vertical axis) as a function of the orientation of the chromophore (referred to as molecular orientation). The light is perpendicularly incident (i.e., at 90 degrees relative to the plane of the diffusing plate) on the diffusion plate with lambertian scattering. As can be seen from FIG. 13, the optical quantum efficiency increases with an increasing degree of molecular orientation, and is relatively constant and highest for about 70 degrees to 90 degrees.

FIG. 14 illustrates a plot of the optical quantum efficiency (vertical axis) as a function of the angle of incidence of the light (horizontal axis) relative to the plane of the diffusing plate 1110 for several orientations of the chromophore. Line 1410 represents a molecular orientation of 90 degrees, line 1420 represents a molecular orientation of 80 degrees, and line 1430 represents a molecular orientation of 70 degrees. As can be seen from FIG. 14, the optical quantum efficiency is similar among the various molecular orientations and approximately constant for light incident at an angle above about 30 degrees. This demonstrates that the power output of the solar concentrator will remain substantially constant with varying angles of incidence of the optical radiation 110 on the diffusing plate 1110. For example, as the sun moves across the sky during a day and the angle of incidence of the solar radiation therefore changes, the power output of the solar concentrator may remain substantially constant as solar radiation is incident at less than 30 degrees only very early and late in the day. Thus, by using the diffusing plate 1110 coupled to an LSC 1120, the power output of the solar concentrator may be maintained at a substantially constant level for changing light conditions. Furthermore, as discussed above, the use of the LSC may increase the power output of the PV cell(s) associated with the concentrator system relative to PV cells that receive non-concentrated light, thereby extending the usefulness of PV systems.

In accordance with certain examples, methods of increasing the efficiency of a PV cell are disclosed. In certain examples, the method comprises providing concentrated optical radiation to two or more photovoltaic cells from a hybrid solar concentrator, as discussed above. The optical radiation may be optically concentrated (e.g., by refraction) and/or concentrated by luminescence, as discussed above. In other examples, the method may further include embedding the PV cells in the solar concentrators to further increase the efficiency of the PV cells. Other methods of using the solar concentrators disclosed herein to increase the efficiency of PV cells and systems including PV cells will be readily selected by the person of ordinary skill in the art, given the benefit of this disclosure.

According to another embodiment, an advantage of the hybrid solar concentrators disclosed herein is that, due to the higher levels of concentration which may be achieved, the hybrid concentrators may be used in photovoltaic systems that harvest light from sources other than the sun, which typically are less bright. For example, embodiments of the solar concentrators may harvest light from engineered light sources such as incandescent or fluorescent light bulbs, as discussed further below. Furthermore, because the embodiments of the solar concentrators may increase the efficiency of the PV cells, they may allow PV cells to be used to power a variety of the devices for which conventional PV systems are too inefficient.

For example, according to one embodiment, the solar concentrators described herein may be used in or with a portable device. Portable devices are those devices that may be placed or moved by a user with ease and typically function using direct current from a battery or fuel cell source. For example, widely distributed sensors, mobile electronics, and communication and entertainment appliances are used in applications that require wireless operability. The spatial dispersion of sensing hardware and other portable devices can be time-synchronized over meters, kilometers or further to monitor large scale systems such as, for example, buildings, city-wide data networks, electrical grid power distribution systems, or even the human body for long periods of time without external data or power hook-up. Accordingly, battery power is often a convenient method for provided portability and wireless use. However, electrochemical storage devices require periodic replacement or recharging, which can be expensive and time consuming. Micropower generation, or the transduction of ambient energy sources from the local environment, offers an attractive route to complete battery replacement and/or decrease in the frequency of battery recharging cycles. Exploiting renewable energy resources in the device's environment, however, offers a power source limited by the device's physical survival rather than an adjunct energy store.

Recent motivation in environmental energy harvesting and energy scavenging has increased as low-power electronics, wireless standards, and miniaturization are increasingly prevalent in the form of sensor networks and mobile devices. Devices that experience a wide range of environmental conditions due to spatially and temporally diverse usage patterns require access to distributed energy sources and a relatively invariant power conversion efficiency dependence on energy intensity. Photovoltaic devices are one method to scavenge energy from local light sources, either in the outdoors from the sun or indoors from engineered light sources.

For portable electronics, the cost-per-area considerations are secondary, as most devices have small areas of exposed surface. To either power the devices in the steady state or contribute to a substantial extension of device lifetime, the photovoltaic devices generally are 1) used in high illumination conditions, 2) possess high power conversion efficiency, or 3) both. Additionally, true device portability is enhanced if the conversion efficiency is independent on illumination intensity and the direction of the light source(s). Conventional photovoltaic devices can exhibit a strong dependence of conversion efficiency on local illumination conditions. These traits are undesirable for use in both outdoor conditions (ambient intensity 100 mW/cm²) and indoor lighting (ambient intensity 1-10 mW/cm²). In addition, photovoltaic devices made from crystalline semiconductors can exhibit a strong dependence of absorption efficiency on illumination direction and exhibit pronounced performance degradation when used indoors where the level of illumination may be only about 1-10% compared to solar irradiance.

Accordingly, any one or more of the solar concentrators described herein may be electrically coupled to a photovoltaic cell and the overall assembly may be electrically coupled to the portable device to provide primary power, charging power or backup power to the portable device. By concentrating the light, as discussed above, indoor concentrated illumination can approximately equal outdoor non-concentrated illumination. Thus, the performance degradation of PV systems used indoors can be mitigated. In addition, due to the logarithmic dependence of photovoltage with light intensity, optical concentration also typically results in higher power conversion.

According to one embodiment, the solar concentrators described herein, when used in combination with a portable device, can provide significant advantageous characteristics including, compatibility with both diffuse and direct illumination. The relative ratio of direct and diffuse light illumination is substantially higher for indoor versus outdoor environments. Conventional photovoltaics are designed for maximal (outdoor) solar conversion efficiency and thus undergo significant performance degradation under purely diffuse lighting conditions. In such conventional systems, the distribution of light absorption within the device thickness strongly affects electrical conversion efficiency (the spectral quantum efficiency varies with wavelength). By contrast, as discussed above, embodiments of the LSCs operate effectively with diffuse optical radiation. In LSCs, the physical depth of the light absorption event does not affect light collection efficiency and thus can convert light with higher efficiency. Compatibility with diffuse light collection also allows simultaneous conversion of light absorbed over multiple collector faces. For example, in a planar configuration, LSCs can concentrate light incident on both front and back sides of its large area faces.

Another advantageous characteristic of a PV system incorporating one or more solar concentrators is that increased optical intensity at the PV cells (due to concentration) will increase electrical output compared to non-concentrated configurations. In addition, the lower ambient light intensity will not, when optically concentrated, overheat the solar cell, allowing passive thermal management to be employed. Since each photon undergoes a bathochromic shift subsequent to absorption and preceding emission by the chromophore, extra energy is removed from the concentrated light that would otherwise contribute to heating potential conversion efficiency degradation.

For the portability of usage required of mobile electronics, it is desirable to achieve high conversion efficiencies when used under low lighting conditions (indoors), as a substantial fraction of use corresponds to these conditions. Incandescent bulbs are designed to match the spectral distribution of the sun; however, fluorescent bulbs are partly more efficient because they do not emit as much light in the infrared spectrum; as such, fluorescent indoor lighting contains a larger portion of its light spectrum within the visible band. Low bandgap PV cells like silicon, cadmium telluride, and copper indium gallium selenide (1-1.4 eV) are ill-suited to extract high power from each photon since their bandgaps fall within the infrared—they are designed for sunlight. PV cells with bandgaps in the visible frequencies enable higher electrical efficiencies as thermalization losses are reduced. Put another way, the semiconductor bandgap(s) of single or multifunction PV cells that correspond to maximal power conversion efficiency for light incident from fluorescent bulbs are within the visible band instead of within the infrared band. As discussed above, embodiments of the solar concentrators can be designed to operate with multiple PV cells having different bandgaps to absorb light with different wavelength ranges so a greater fraction of each photon's power will be extracted. In one example, LSCs can be designed to concentrate light at higher energies than that corresponding to the bandgap for optimal power conversion efficiency of outdoor light (about 1.1-1.3 V); as such, they can exhibit high conversion efficiencies when operating in indoor environments.

Another advantageous characteristic of a PV system incorporating one or more solar concentrators is that for devices where aesthetic appearance is important, the uniform (homogenous or un-patterned) frontal appearance of LSCs possesses strong market advantages in segments where consumers value visual structure. In addition, the color of a LSC can be tailored at the time of manufacture, enabling visual customization, a substantial value in markets driven by aesthetic appearance, like personal entertainment, communication, and management devices.

Illustrative mobile devices that utilize batteries that can be either replaced, have their operational lifetime increased, or otherwise reduced in size, include but are not limited to: digital audio players (MP3, or “MPEG Layer-3”, or “Moving Picture Experts Group Layer 3” players), mobile phones (“cell phones” and portable phones), personal digital assistants (PDAs), portable computers (laptop computers), image sensors, cameras, mobile environmental sensors (for instance: audio, thermal, optical, vibrational, chemical, and weather monitoring) and other devices that commonly use batteries. For example, a solar concentrator may be placed on a surface of a vehicle, e.g., a car, recreational vehicle, golf cart, etc., to provide power to one or more battery storage devices used to provide starting, primary power or accessory power, e.g., power for operating air conditioning units, heating units, stoves, etc. in a recreational vehicle.

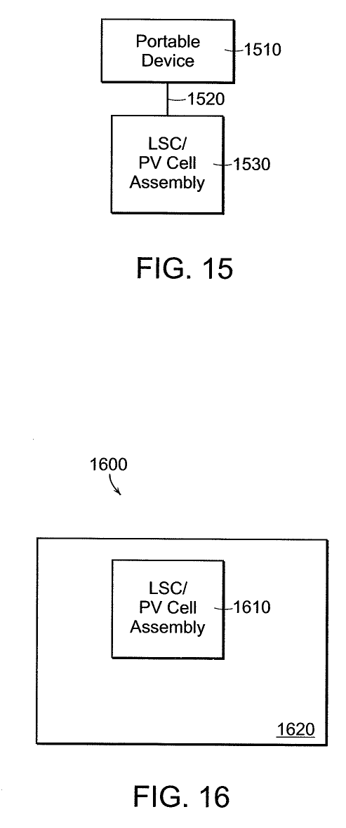

Two illustrative configurations of portable devices that are coupled to a solar concentrator are shown in FIGS. 15 and 16. The dimensions in FIGS. 15 and 16 are arbitrary and no size or relative size should be implied or inferred. Referring to FIG. 15, a portable device 1510 is electrically coupled to a LSC/PV cell assembly 1520 though interconnect 1530. The LSC/PV cell assembly 1520 is separate from the portable device 1510, and current is supplied to the portable device 1510 through the interconnect 1530. The LSC of the LSC/PV assembly 1520 may be any of those described herein, for example, those that include one or more of a chromophore, a chromophore assembly, an anti-Stokes material or both. Similarly, the PV cell of the LSC/PV cell assembly 1520 may be any PV cell including the thin film PV cells described herein. In addition, the LSC/PV cell assembly may include more than one PV cell as described herein with respect to embodiments that include two or more PV cells, e.g., two or more PV cells having different efficiencies and/or bandgaps, as discussed above.

Referring to FIG. 16, an LSC/PV cell assembly 1610 is shown as in the housing 1620 of a portable device 1600. The LSC/PV assembly 1610 may be positioned along one or more surfaces that would receive incident light during operation or storage of the portable device. For example, the LSC/PV assembly 1610 may be positioned on an upper surface of a mobile phone facing away from a user such that during use of the mobile phone, incident sunlight or ambient light may be captured by the LSC/PV cell assembly 1610 to charge the mobile phone battery.

In embodiments where a LSC/PV cell assembly is used with a mobile device other suitable components, such as voltage converters, amplifiers, conditioners and the like may be used to provide a desired voltage output, waveform, intensity and the like. Such devices are conventionally known in the art and will be readily selected for use by the person of ordinary skill in the art, given the benefit of this disclosure.

In one embodiment, an LSC may be used for indoor light harvesting. For example, electronic shelf labels may include an LSC/PV cell assembly that can be electronically coupled to sensors, computers and the like. The electronic shelf label (ESL) may harvest light from indoor light sources, e.g., fluorescent bulbs, halogen bulbs, etc. used to provide ambient lighting in a room. The ESL may be electrically coupled to a device by placement on a shelf or by placement in the housing of the device. Irrespective of where the ESL is placed, the LSC/PV assembly desirably can receive incident light from the overhead light sources and convert that light to a current, which may be provided to the sensor, computer or other electronic device included in the ESL.

Having thus described several aspects of at least one embodiment, it is to be appreciated various alterations, modifications, and improvements will readily occur to those skilled in the art. Such alterations, modifications, and improvements are intended to be part of this disclosure and are intended to be within the scope of the invention. The examples discussed herein serve to illustrate some of the novel features, aspect and examples of the technology disclosed herein and should not be construed as limiting the scope of the appended claims. Accordingly, the foregoing description and drawings are by way of example only, and the scope of the invention should be determined from proper construction of the appended claims, and their equivalents.

What is claimed is:

1. A hybrid solar concentrator comprising:
a first luminescent solar concentrator comprising a first substrate having a first chromophore disposed in or on the first substrate to receive optical radiation, the first chromophore effective to absorb at least one wavelength of the optical radiation and to emit radiation;
a first photovoltaic cell optically coupled to the first luminescent solar concentrator and configured to receive at least some of the emitted radiation; and
an optical device optically coupled to the first luminescent solar concentrator and comprising a second photovoltaic cell configured to receive at least some of the optical radiation transmitted through the first substrate;
wherein the first substrate has a curvature to refract and direct the at least some of the optical radiation transmitted through the first substrate toward the optical device.

2. The hybrid solar concentrator as claimed in claim 1, wherein the optical device comprises a second substrate; and
wherein the second photovoltaic cell is a thin-film photovoltaic cell coupled to the second substrate.

3. The hybrid solar concentrator as claimed in claim 2, wherein the second substrate comprises any one of cadmium telluride, cadmium indium gallium selenide, copper indium sulfide, amorphous silicon, monocrystalline silicon, multicrystalline silicon, amorphous silicon/polysilicon micromorph, cadmium selenide, aluminum antimonide, indium phosphide, aluminum arsenide, gallium phosphide, and gallium antimonide.

4. The hybrid solar concentrator as claimed in claim 1, wherein the first and second photovoltaic cells are each selected to have different bandgaps.

5. The hybrid solar concentrator as claimed in claim 1, wherein the emitted radiation has a wavelength that is red-shifted relative to the first wavelength.

6. The hybrid solar concentrator as claimed in claim 1, wherein the first photovoltaic cell is coupled to a first surface of the first substrate; and
wherein the optical device is arranged such that the second photovoltaic cell receives at least some of the optical radiation transmitted through a second surface of the first substrate.

7. The hybrid solar concentrator as claimed in claim 6, wherein the first and second surfaces of the first substrates are at substantially 90 degrees relative to one another; and
wherein the optical device is disposed below the first substrate.

8. The hybrid solar concentrator as claimed in claim 1, wherein the optical device comprises a second luminescent solar concentrator optically coupled to the second photovoltaic cell;
wherein the second luminescent solar concentrator comprises a second substrate having a second chromophore disposed in or on the second substrate to receive at least some of the optical radiation transmitted through the first substrate, the second chromophore effective to absorb at least one wavelength of the transmitted optical radiation and to emit second radiation; and
wherein the second photovoltaic cell is configured to receive at least some of the second radiation.

9. The hybrid solar concentrator as claimed in claim 1, wherein the optical device comprises a lens configured to focus the at least some optical radiation transmitted through the first substrate onto the second photovoltaic cell.

10. The hybrid solar concentrator as claimed in claim 1, wherein the optical device is disposed below a first surface of the first substrate; and
wherein the first surface of the first substrate is curved to refract at least some of the optical radiation transmitted through the first substrate onto the second photovoltaic cell.

11. The hybrid solar concentrator as claimed in claim 1, further comprising at least one wavelength selective mirror disposed on the first substrate, the at least one wavelength selective mirror configured to transmit incident light in a first wavelength range and to reflect incident light in a second wavelength range.

12. The hybrid solar concentrator as claimed in claim 11, wherein the first photovoltaic cell has a first bandgap including the second wavelength range; and
wherein the second photovoltaic cell has a second bandgap including the first wavelength range.

13. A solar concentrator comprising:
a diffusing plate that receives incident optical radiation and transmits diffuse optical radiation;
a substrate disposed below and optically coupled to the diffusing plate, the substrate having a chromophore disposed in or on the substrate to receive the diffuse optical radiation, the chromophore effective to absorb at least one wavelength of the diffuse optical radiation and to emit emitted radiation; and
a first photovoltaic cell optically coupled to the substrate and configured to receive at least some of the emitted radiation.

14. The solar concentrator as claimed in claim 13, wherein the diffusing plate is configured for lambertian scattering of the optical radiation.

15. The solar concentrator as claimed in claim 13, wherein the emitted radiation has a wavelength that is red-shifted relative to the first wavelength.

16. The solar concentrator as claimed in claim 13, further comprising an anti-reflection coating disposed on at least one surface of the diffusing plate.

17. The solar concentrator as claimed in claim 13, wherein the substrate comprises any one of glass, cadmium telluride, cadmium indium gallium selenide, copper indium sulfide, amorphous silicon, monocrystalline silicon, multicrystalline silicon, and amorphous silicon/polysilicon micromorph.

18. The solar concentrator as claimed in claim 13, wherein the substrate is a glass comprising a refractive index of at least 1.7.

19. The solar concentrator as claimed in claim 13, wherein the incident optical radiation is generated by an engineered light source.

20. The solar concentrator as claimed in claim 13, wherein the diffusing plate comprises one of opalescent glass, frosted glass, mechanically roughened plastics and glasses, chemically roughened plastics and glasses, surface-pattered plastics, and holographically patterned plastics.

21. The solar concentrator as claimed in claim 13, wherein an orientation of the chromophore is in a range of approximately 70-90 degrees relative to a front face of the substrate.
